(19) United States
(12) Patent Application Publication
(10) Pub. No.: US 2026/0013147 A1
(43) Pub. Date: Jan. 8, 2026

(54) SEMICONDUCTOR STRUCTURE AND MANUFACTURING METHOD THEREOF

(71) Applicant: United Microelectronics Corp., Hsinchu (TW)

(72) Inventors: Xin Feng, Singapore (SG); Chien-Ming Lai, Tainan City (TW); Cheng-Yu Hsieh, Singapore (SG)

(73) Assignee: United Microelectronics Corp., Hsinchu (TW)

(21) Appl. No.: 18/772,292

(22) Filed: Jul. 15, 2024

(30) Foreign Application Priority Data
Jul. 4, 2024 (TW) 113125107

(51) Int. Cl. H01L 21/768; H01L 23/48

(52) U.S. Cl. CPC H10D 1/042; H01L 21/76898; H01L 23/481; H10D 1/716

(57) ABSTRACT

Disclosed is a semiconductor structure including a substrate, a capacitor structure, an interlayer dielectric, a contact, a protective layer, and a conductive hole. The capacitor structure is disposed in the substrate. The interlayer dielectric is disposed on the substrate, and exposes a portion of the capacitor structure. The contact is disposed in the interlayer dielectric, and is electrically connected to the capacitor structure. The protective layer is disposed on the interlayer dielectric, and covers the contact. The conductive hole penetrates the protective layer and the interlayer dielectric. A top surface of the conductive hole is higher than a top surface of the contact. A manufacturing method of a semiconductor structure is also provided.

### CROSS-REFERENCE TO RELATED APPLICATION

This application claims the priority benefit of Taiwan application serial no. 113125107, filed on Jul. 4, 2024. The entirety of the above-mentioned patent application is hereby incorporated by reference herein and made a part of this specification.

### BACKGROUND

### Technical Field

The disclosure relates to a semiconductor structure, and particularly relates to a semiconductor structure including a conductive hole and a capacitor structure.

### Description of Related Art

In the conventional semiconductor structure including the conductive hole and the capacitor structure, when a planarization process is performed on a through hole filled with copper, the contact electrically connected to the capacitor structure is not protected. Therefore, the contact is easily contaminated by copper after the planarization process is performed, which reduces the yield of the final semiconductor structure.

### SUMMARY

The disclosure provides a semiconductor structure with a good yield.

Some embodiments of the disclosure provide a semiconductor structure, which includes a substrate, a capacitor structure, an interlayer dielectric, a contact, a protective layer, and a conductive hole. The capacitor structure is disposed in the substrate. The interlayer dielectric is disposed on the substrate and exposes a portion of the capacitor structure. The contact is disposed in the interlayer dielectric and is electrically connected to the capacitor structure. The protective layer is disposed on the interlayer dielectric and covers the contact. The conductive hole penetrates the protective layer and the interlayer dielectric. The top surface of the conductive hole is higher than the top surface of the contact. The disclosure further provides a manufacturing method of a semiconductor structure.

The disclosure provides a manufacturing method of a semiconductor structure with a low manufacturing cost.

Other embodiments of the disclosure provide a manufacturing method of a semiconductor structure, which includes the following steps. Step (1): A capacitor structure is formed in a substrate. Step (2): An interlayer dielectric is formed on the substrate, in which the interlayer dielectric covers the capacitor structure. Step (3): A contact is formed in the interlayer dielectric. Step (4): A protective layer is formed on the interlayer dielectric, in which the protective layer covers the contact. Step (5): A trench penetrating the protective layer and the interlayer dielectric is formed, in which the trench is further formed in the substrate. Step (6): A conductive layer is formed on the protective layer, in which a portion of the conductive layer is filled in the trench. Step (7): A planarization process is performed on the conductive layer to form a conductive hole.

Based on the above, in the semiconductor structure and the manufacturing method thereof provided by the disclosure, when the planarization process is performed on the conductive layer, the contact is covered by the protective layer disposed thereon. Therefore, the possibility of the contact being contaminated in the formation process of the conductive hole can be reduced. Based on the above, the semiconductor structure provided by the disclosure can have a good yield. Furthermore, the manufacturing method of the semiconductor structure provided by the disclosure has simple steps, and thus the manufacturing cost is low.

### BRIEF DESCRIPTION OF THE DRAWINGS

FIG. 1A to FIG. 1D are schematic diagrams of a flow of a manufacturing method of a semiconductor structure according to an embodiment of the disclosure.

FIG. 2 is a partial top view schematic diagram of a disposition relationship between a capacitor structure and a conductive hole in the semiconductor structure according to an embodiment of the disclosure.

### DESCRIPTION OF THE EMBODIMENTS

Examples are listed below together with the accompanying drawings to describe the disclosure in detail, but the examples provided are not intended to limit the scope of the disclosure. Furthermore, the drawings of the disclosure are for illustrative purposes only, and specific elements in the drawings are not drawn to actual scale. In order to make the disclosure more comprehensible, the same element is identified using the same reference numeral in the following description.

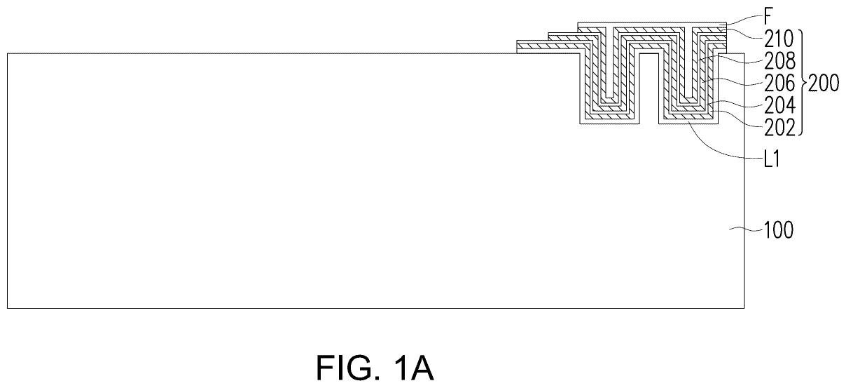

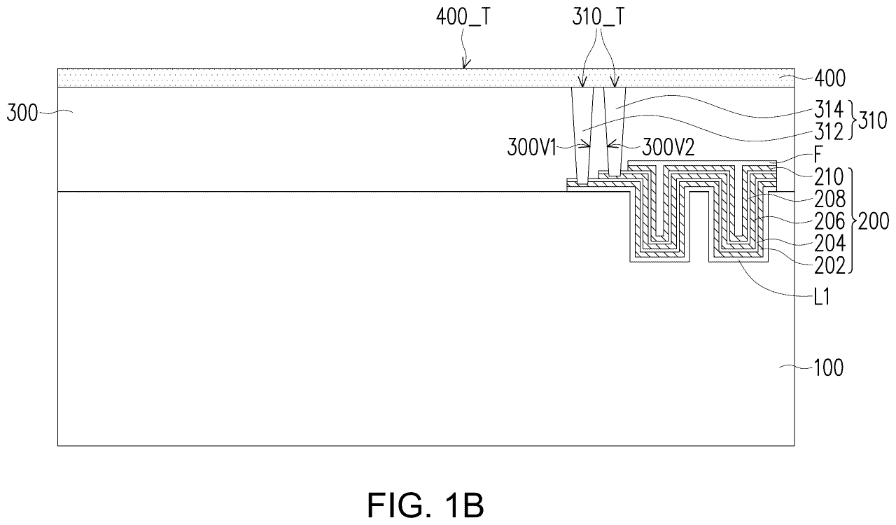

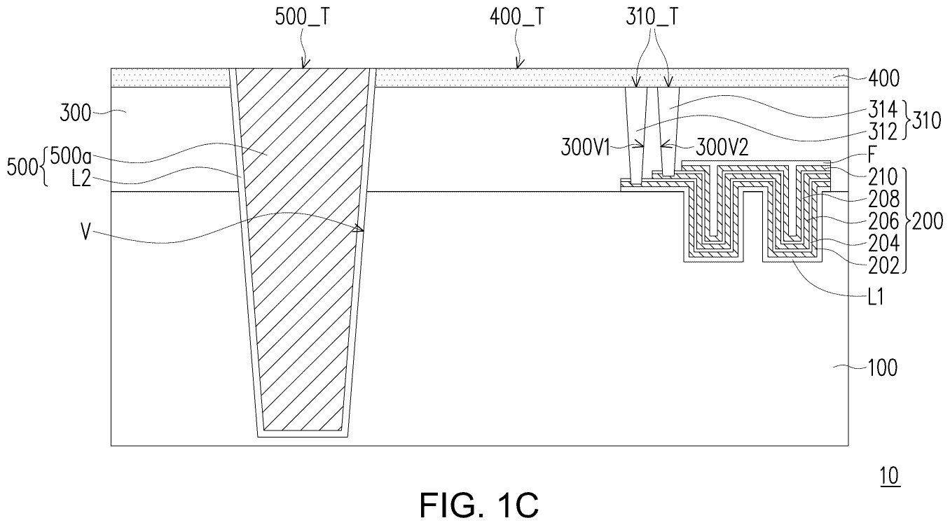

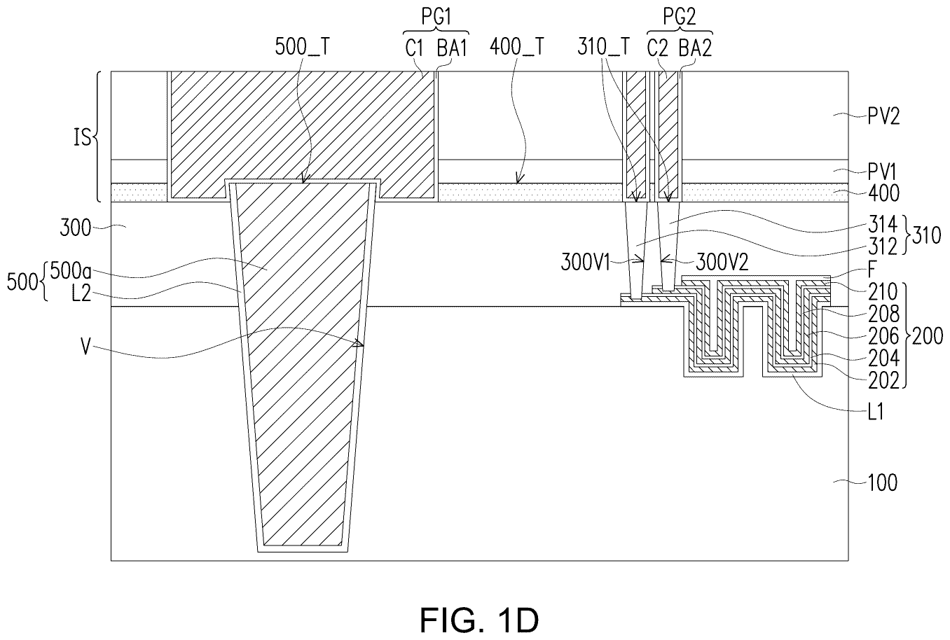

FIG. 1A to FIG. 1D are schematic diagrams of a flow of a manufacturing method of a semiconductor structure according to an embodiment of the disclosure.

Referring to FIG. 1A to FIG. 1D, in this embodiment, a semiconductor structure 10 may be formed by performing the following steps, but the disclosure is not limited thereto.

Step (1) is performed: a capacitor structure 200 is formed in a substrate 100.

Referring to FIG. 1A, in some embodiments, the substrate 100 may be a semiconductor substrate, but the disclosure is not limited thereto. The material of the substrate 100 may include, for example, elemental semiconductors, compound semiconductors, alloy semiconductors, or other suitable materials. For example, the material of the substrate 100 may include silicon, germanium, indium antimonide, indium arsenide, indium phosphide, gallium nitride, gallium arsenide, gallium antimonide, lead telluride, or combinations thereof. In other embodiments, the substrate 100 may be a silicon on insulator (SOI) substrate. In this embodiment, the substrate 100 is a Si interposer, but the disclosure is not limited thereto.

The capacitor structure 200 is, for example, a deep trench capacitor (DTC) structure. In detail, the capacitor structure 200 may be formed by performing the process described below, but the disclosure is not limited thereto.

Step (A): multiple trenches are formed in the substrate 100. In some embodiments, the multiple trenches may be formed by performing an etching process. For example, plasma may be used to perform a dry etching process on the substrate 100 to form the multiple trenches, but the disclosure is not limited thereto.

Step (B): a liner layer L1 is formed in the multiple trenches. In some embodiments, the liner layer L1 may be formed by performing a chemical vapor deposition process, a thermal oxidation process, or a combination thereof, but the disclosure is not limited thereto. In some embodiments, the material of the liner layer L1 may include oxide. For example, the liner layer L1 may include silicon oxide, but the disclosure is not limited thereto. In some embodiments, the liner layer L1 may be a single-layer structure or a multi-layer structure, but the disclosure is not limited thereto.

Step (C): a conductive layer 202 is formed in the multiple trenches, in which the conductive layer 202 is disposed on the liner layer L1. In some embodiments, the conductive layer 202 may be formed by performing the chemical vapor deposition process. For example, pyrolysis of silane may be used to deposit the conductive layer 202 in the multiple trenches, but the disclosure is not limited thereto. In this embodiment, the material of the conductive layer 202 includes polycrystalline silicon, but the disclosure is not limited thereto.

Step (D): a dielectric layer 204 is formed in the multiple trenches. In some embodiments, the dielectric layer 204 may be formed by performing the chemical vapor deposition process, an atomic layer deposition process, or a combination thereof, but the disclosure is not limited thereto. In some embodiments, the material of the dielectric layer 204 may include nitride or oxide with a relatively large dielectric constant. For example, the liner layer L1 may include silicon nitride or aluminum oxide, but the disclosure is not limited thereto. In some embodiments, the dielectric layer 204 may be a single-layer structure or a multi-layer structure, but the disclosure is not limited thereto.

Step (E): Step (C) and Step (D) are performed repeatedly in sequence, in which the number of times Step (C) is performed is one more than the number of times Step (D) is performed. In this embodiment, Step (C) is performed three times and Step (D) is performed twice to sequentially form the conductive layer 202 disposed on the liner layer L1, the dielectric layer 204 disposed on the conductive layer 202, a conductive layer 206 disposed on the dielectric layer 204, a dielectric layer 208 disposed on the conductive layer 206, and a conductive layer 210 disposed on the dielectric layer 208, but the disclosure is not limited thereto. In other embodiments, Step (C) and Step (D) may be performed for other times. It is worth mentioning that the conductive layer 206 exposes a portion of the conductive layer 202, and the conductive layer 210 exposes a portion of the conductive layer 206, so as to facilitate the subsequent process of forming contacts 310. For the materials included in each of the conductive layer 206, the dielectric layer 208, and the conductive layer 210 and the formation methods thereof, reference may be made to the above embodiments, so details will not be repeated here.

Step (E): a filling layer F is formed in the multiple trenches, in which the filling layer F is disposed on the conductive layer 210 and fills the multiple trenches. The materials included in the filling layer F and the formation method thereof may be the same as or similar to the materials included in the dielectric layer 204 and the formation method thereof, so details will not be repeated here.

At this point, the manufacturing method of the capacitor structure 200 of this embodiment is completed, but the manufacturing method of the capacitor structure 200 provided by the disclosure is not limited thereto. Although only one capacitor structure 200 is shown in FIG. 1A, the capacitor structure 200 of the disclosure may be disposed in plural quantities, in which the multiple capacitor structures 200 may be connected in parallel to increase the capacitance density of the semiconductor structure 10.

Step (2) is performed: an interlayer dielectric 300 is formed on the substrate 100, in which the interlayer dielectric 300 covers the capacitor structure 200.

Referring to FIG. 1B, in some embodiments, the interlayer dielectric 300 may be formed by performing the chemical vapor deposition process, but the disclosure is not limited thereto. The material of the interlayer dielectric 300 may, for example, include an oxide with a relatively low dielectric constant to reduce the possibility of capacitive coupling between adjacent conductive structures. For example, the interlayer dielectric 300 may include tetraethoxysilane (TEOS), but the disclosure is not limited thereto.

Step (3) is performed: the contact 310 is formed in the interlayer dielectric 300.

Please continue to refer to FIG. 1B. The contact 310 may be formed by performing the process described below, but the disclosure is not limited thereto.

First, a first through hole 300V1 and a second through hole 300V2 are formed in the interlayer dielectric 300. In some embodiments, the first through hole 300V1 and the second through hole 300V2 may be formed by performing the etching process, but the disclosure is not limited thereto. The first through hole 300V1 and the second through hole 300V2, for example, respectively expose portions of the conductive layer 202 and the conductive layer 206. In detail, the etching process may further remove a portion of the dielectric layer 204 disposed on the conductive layer 202 and a portion of the dielectric layer 208 disposed on the conductive layer 206.

Afterward, the conductive material is filled in the first through hole 300V1 and the second through hole 300V2 to respectively form a first contact 312 and a second contact 314, in which the contacts 310 include the first contact 312 and the second contact 314. In this embodiment, the conductive material filled in the first through hole 300V1 and the second through hole 300V2 includes tungsten, but the disclosure is not limited thereto.

At this point, the manufacturing method of the contact 310 in this embodiment is completed, but the manufacturing method of the contact 310 provided by the disclosure is not limited thereto.

Step (4) is performed: a protective layer 400 is formed on the interlayer dielectric 300, in which the protective layer 400 covers the contact 310.

Please continue to refer to FIG. 1B. In some embodiments, the protective layer 400 may be formed by performing the chemical vapor deposition process, but the disclosure is not limited thereto. The material of the protective layer 400 may include, for example, suitable dielectric materials. For example, the material of the protective layer 400 includes ultraviolet-transparent silicon nitride (UVSIN), but the disclosure is not limited thereto.

Step (5) is performed: a trench V penetrating the protective layer 400 and the interlayer dielectric 300 is formed, in which the trench V is further formed in the substrate 100.

Referring to FIG. 1C, in some embodiments, a patterning process may be performed to form the trench V penetrating the protective layer 400 and the interlayer dielectric 300. For example, the trench V may be formed by performing a photolithography etching process, but the disclosure is not limited thereto. In this embodiment, the trench V is further formed in the substrate 100. In detail, a bottom portion of the trench V exposes a portion of the substrate 100, and a sidewall of the trench V comprises a portion of the substrate 100, a portion of the dielectric layer 300, and a portion of the protective layer 400.

Step (6) is performed: a conductive layer 500a is formed on the protective layer 400, in which a portion of the conductive layer 500a is filled in the trench V.

Please continue to refer to FIG. 1C. In some embodiments, the conductive layer 500a may be formed in the trench V by performing an electroplating process, but the disclosure is not limited thereto. In this embodiment, the material of the conductive layer 500a includes copper, but the disclosure is not limited thereto.

Please continue to refer to FIG. 1C. In some embodiments, before forming the conductive layer 500a in the trench V, a liner layer L2 may be formed in the trench V first. In some embodiments, the liner layer L2 may be formed by performing the atomic layer deposition process, but the disclosure is not limited thereto. The material of the liner layer L2 may, for example, include suitable dielectric materials. For example, the material of the liner layer L2 includes silicon oxide, but the disclosure is not limited thereto.

Step (7) is performed: a planarization process is performed on the conductive layer 500a to form a conductive hole 500.

Referring to FIG. 1D, in some embodiments, the planarization process performed on the conductive layer 500a may include a chemical mechanical polishing (CMP) process, but the disclosure is not limited thereto. In this embodiment, the planarization process is performed on the conductive layer 500a to remove the conductive layer 500a not disposed in the trench V. It is worth mentioning that in this embodiment, the planarization process performed on the conductive layer 500a may further remove the liner layer L2 disposed on a top surface of the protective layer 400.

In this embodiment, when performing the planarization process on the conductive layer 500a, since the contact 310 is covered by the protective layer 400 disposed thereon, the possibility of the contact 310 being contaminated in the formation process of the conductive hole 500 can be reduced.

In addition, in this embodiment, since the contact 310 is covered by the protective layer 400, after the planarization process is performed on the conductive layer 500a, a top surface 500_T of the conductive hole 500 is substantially flush with a top surface 400_T of the protective layer 400, so that the top surface 500_T of the conductive hole 500 is higher than a top surface 310_T of the contact 310.

At this point, the manufacturing method of the semiconductor structure 10 of this embodiment is completed, but the manufacturing method of the semiconductor structure 10 provided by the disclosure is not limited thereto.

After the semiconductor structure 10 is formed, subsequent interconnection processes may be performed. In detail, referring to FIG. 1E, in some embodiments, an interconnection structure IS may be formed on the semiconductor structure 10. In this embodiment, the interconnection structure IS includes a dielectric layer PV1, a dielectric layer PV2, a plug PG1, and a plug PG2, but the disclosure is not limited thereto.

The dielectric layer PV1 is, for example, disposed on the protective layer 400. In some embodiments, the dielectric layer PV1 may be formed by performing the chemical vapor deposition process, but the disclosure is not limited thereto. The material of the dielectric layer PV1 may, for example, include suitable dielectric materials. For example, the material of the dielectric layer PV1 includes silicon nitride, but the disclosure is not limited thereto.

The dielectric layer PV2 is, for example, disposed on the dielectric layer PV1. In some embodiments, the dielectric layer PV2 may be formed by performing the chemical vapor deposition process, but the disclosure is not limited thereto. The material of the dielectric layer PV2 may, for example, include suitable dielectric materials. For example, the material of the dielectric layer PV2 includes silicon oxide, but the disclosure is not limited thereto.

The plug PG1 is, for example, disposed on the conductive hole 500, and is, for example, electrically connected to the conductive hole 500. In detail, the dielectric layer PV1 and the dielectric layer PV2 include an opening exposing a portion of the conductive hole 500, and the plug PG1 may be electrically connected to the conductive hole 500 through the opening. In some embodiments, the plug PG1 may be formed by performing the electroplating process, but the disclosure is not limited thereto. The plug PG1 may include, for example, a barrier layer BA1 and a conductive layer C1. The material of the barrier layer BA1 may include, for example, tantalum nitride, titanium nitride, tantalum, titanium, or a combination thereof, and the material of the conductive layer C1 may include, for example, copper, but the disclosure is not limited thereto.

The plug PG2 is, for example, disposed on the contact 310, and is, for example, electrically connected to the contact 310. In detail, in this embodiment, a patterning process is further performed on the protective layer 400, so that the protective layer 400 includes an opening exposing a portion of the contact 310, and the dielectric layer PV1 and the dielectric layer PV2 further include another opening exposing a portion of the contact 310. In this way, the plug PG2 may be electrically connected to the corresponding contact 310 through the communicative openings mentioned above. In some embodiments, the plug PG2 may be formed by performing the electroplating process, but the disclosure is not limited thereto. The plug PG2 may include, for example, a barrier layer BA2 and a conductive layer C2. The material of the barrier layer BA2 may include, for example, tantalum nitride, titanium nitride, tantalum, titanium, or a combination thereof, and the material of the conductive layer C2 may include, for example, copper, but the disclosure is not limited thereto.

In addition, in some embodiments, a thinning process may be performed on the substrate 100 so that the conductive hole 500 penetrates the substrate 100 to form a conductive through hole. In this embodiment, the conductive through hole is a through silicon via (TSV), but the disclosure is not limited thereto.

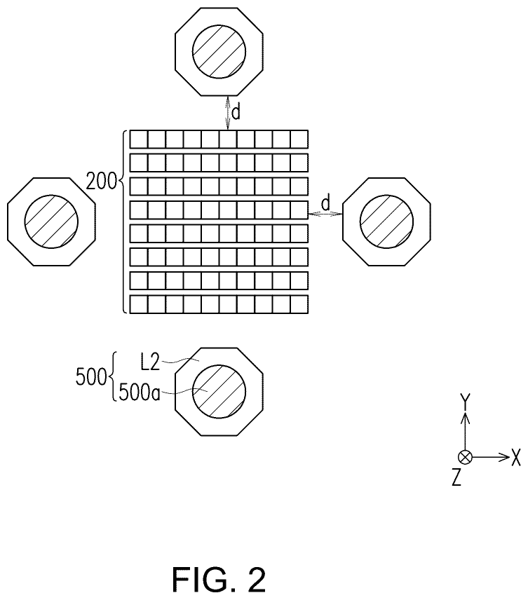

The structure of the semiconductor structure 10 of this embodiment will be briefly introduced below with reference to FIG. 1C and FIG. 2, but the disclosure is not limited thereto.

Please refer to FIG. 1C. In this embodiment, the semiconductor structure 10 includes the substrate 100, the capacitor structure 200, the interlayer dielectric 300, the contact 310, the protective layer 400, and the conductive hole 500. In some embodiments, the semiconductor structure 10 may be applied to the Chip on Wafer on Substrate (CoWoS) packaging technology. Specifically, multiple semiconductor dies (not shown) may be disposed at the same horizontal level on the semiconductor structure 10 to achieve a 2.5D packaging structure including the multiple semiconductor dies with different functions being placed side by side horizontally, but the disclosure is not limited thereto.

For a detailed introduction to the substrate 100, reference may be made to the above embodiments, so details will not be repeated here. In some embodiments, the substrate 100 may be a Si interposer, but the disclosure is not limited thereto.

The capacitor structure 200 is, for example, disposed in the substrate 100, and is, for example, a deep trench capacitor structure. In detail, the capacitor structure 200 includes, for example, multiple conductive layers and multiple dielectric layers, in which the number of the multiple conductive layers is one more than the number of the multiple dielectric layers. In this embodiment, the capacitor structure 200 includes three conductive layers and two dielectric layers. In detail, the structure of the capacitor structure 200 of this embodiment includes the conductive layer 202, the dielectric layer 204, the conductive layer 206, the dielectric layer 208, and the conductive layer 210, in which the dielectric layer 204 is disposed between the conductive layer 202 and the conductive layer 206, and the dielectric layer 208 is disposed between the conductive layer 210 and the conductive layer 206, but the disclosure is not limited thereto. For a detailed introduction to the capacitor structure 200, reference may be made to the above embodiments, so details will not be repeated here.

The interlayer dielectric 300 is, for example, disposed on the substrate 100, and exposes, for example, a portion of the capacitor structure 200. In detail, in this embodiment, the interlayer dielectric 300 includes the first through hole 300V1 and the second through hole 300V2 exposing portions of the capacitor structure 200. In this embodiment, the first through hole 300V1 of the interlayer dielectric 300 exposes a portion of the conductive layer 202, and the second through hole 300V2 of the interlayer dielectric 300 exposes a portion of the conductive layer 206. For a detailed introduction to the interlayer dielectric 300, reference may be made to the above embodiments, so details will not be repeated here.

The contacts 310 are, for example, disposed in the interlayer dielectric 300, and are, for example, electrically connected to the capacitor structure 200 through the first through hole 300V1 and the second through hole 300V2. In detail, the contacts 310 include the first contact 312 and the second contact 314, in which the first contact 312 is electrically connected to the conductive layer 202 of the capacitor structure 200, and the second contact 314 is electrically connected to the conductive layer 206 of the capacitor structure 200. For detailed introduction to the contact 310, reference may be made to the above embodiments, so details will not be repeated here.

The protective layer 400 is, for example, disposed on the interlayer dielectric 300, and covers the contact 310, for example. For a detailed introduction to the protective layer 400, reference may be made to the above embodiments, so details will not be repeated here.

The conductive hole 500, for example, penetrates the protective layer 400 and the interlayer dielectric 300, and is, for example, further formed in the substrate 100. The conductive hole 500 includes, for example, the conductive layer 500a disposed in the trench V and the liner layer L2 disposed between the trench V and the conductive layer 500a. In this embodiment, since the contact 310 is covered by the protective layer 400, the top surface 500_T of the conductive hole 500 is higher than the top surface 310_T of the contact 310.

Please refer to FIG. 2, which shows a disposition relationship between the capacitor structure 200 and the conductive hole 500 in the semiconductor structure 10. In a top-view direction Z of the substrate 100, a plurality of capacitor structures 200 are, for example, arranged in an array arrangement in a two-dimensional space, and a plurality of conductive holes 500 are, for example, arranged in a manner of surrounding the plurality of capacitor structures 200, but the disclosure is not limited thereto. In some embodiments, a distance d between the conductive hole 500 and the nearest capacitor structure 200 in a direction X or a direction Y is 2 microns to 12 microns, but the disclosure is not limited thereto.

In summary, in the semiconductor structure and the manufacturing method thereof provided by the disclosure, when the planarization process is performed on the conductive layer, the contact is covered by the protective layer disposed thereon. Therefore, the possibility of the contact being contaminated in the formation process of the conductive hole can be reduced. Based on the above, the semiconductor structure provided by the disclosure can have a good yield. Furthermore, the manufacturing method of the semiconductor structure provided by the disclosure has simple steps, and thus the manufacturing cost is low.

What is claimed is:

1. A semiconductor structure, comprising:
a substrate;
a capacitor structure, disposed in the substrate;
an interlayer dielectric, disposed on the substrate and exposing a portion of the capacitor structure;
a contact, disposed in the interlayer dielectric and electrically connected to the capacitor structure;
a protective layer, disposed on the interlayer dielectric and covering the contact; and
a conductive hole, penetrating the protective layer and the interlayer dielectric,
wherein a top surface of the conductive hole is higher than a top surface of the contact.

2. The semiconductor structure as claimed in claim 1, wherein the capacitor structure comprises a first conductive layer, a first dielectric layer, a second conductive layer, a second dielectric layer, and a third conductive layer, the first dielectric layer is disposed between the first conductive layer and the second conductive layer, and the second dielectric layer is disposed between the second conductive layer and the third conductive layer.

3. The semiconductor structure as claimed in claim 1, wherein a material of the interlayer dielectric comprises tetraethoxysilane, and a material of the protective layer comprises ultraviolet-transparent silicon nitride.

4. The semiconductor structure as claimed in claim 1, wherein the top surface of the conductive hole is flush with a top surface of the protective layer.

5. The semiconductor structure as claimed in claim 1, wherein a distance between the conductive hole and a nearest capacitor structure is 2 microns to 12 microns.

6. A manufacturing method of a semiconductor structure, comprising:
forming a capacitor structure in a substrate;
forming an interlayer dielectric on the substrate, wherein the interlayer dielectric covers the capacitor structure;
forming a contact in the interlayer dielectric;
forming a protective layer on the interlayer dielectric, wherein the protective layer covers the contact;
forming a trench penetrating the protective layer and the interlayer dielectric, wherein the trench is further formed in the substrate;
forming a conductive layer on the protective layer, wherein a portion of the conductive layer is filled in the trench; and
performing a planarization process on the conductive layer to form a conductive hole.

7. The manufacturing method of the semiconductor structure as claimed in claim 6, further comprising forming a liner layer on the protective layer before forming the conductive layer, wherein a portion of the liner layer is filled in the trench.

8. The manufacturing method of the semiconductor structure as claimed in claim 7, wherein in performing the planarization process on the conductive layer, the liner layer disposed on a top surface of the protective layer is further removed.

9. The manufacturing method of the semiconductor structure as claimed in claim 6, further comprising performing a thinning process on the substrate so that the conductive hole penetrates the substrate to form a conductive through hole.

10. The manufacturing method of the semiconductor structure as claimed in claim 6, further comprising forming an interconnection structure, wherein the interconnection structure is electrically connected to the contact and the conductive hole.
